(19) United States
(12) Patent Application Publication
(10) Pub. No.: US 2019/0318925 A1
(43) Pub. Date: Oct. 17, 2019

(54) Monoorganoaminodisilane Precursors and Methods for Depositing Films Comprising Same

(71) Applicant: Versum Materials US, LLC, Tempe, AZ (US)

(72) Inventors: Xinjian Lei, Tempe, AZ (US); Meiliang Wang, Tempe, AZ (US); Madhukar B. Rao, Tempe, AZ (US)

(73) Assignee: Versum Materials US, LLC, Tempe, AZ (US)

(21) Appl. No.: 16/373,919

(22) Filed: Apr. 3, 2019

Related U.S. Application Data
(60) Provisional application No. 62/656,044, filed on Apr. 11, 2018.

(51) Int. Cl. H01L 21/02; C07F 7/10; C23C 16/34; C23C 16/36; C23C 16/50; C23C 16/455

(52) U.S. Cl. CPC H01L 21/02211; C07F 7/10; C23C 16/345; C23C 16/36; C23C 16/50; H01L 21/0228; C23C 16/45536; H01L 21/02167; H01L 21/0217; H01L 21/02274; C23C 16/45553

(57) ABSTRACT

Described herein are precursors and methods for forming silicon-containing films. In one aspect, there is provided a precursor of Formula I:

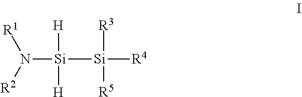

as described herein.

### CROSS REFERENCE TO RELATED PATENT APPLICATIONS

The present patent application claims the benefit of U.S. Provisional Patent Application Ser. No. 62/656,044 filed Apr. 11, 2018 which is hereby incorporated by reference.

### BACKGROUND OF THE INVENTION

Precursors, particularly monoorganoaminodisilane, and compositions thereof that can be used for the deposition of silicon-containing films, including but not limited to, silicon amorphous silicon, crystalline silicon, silicon nitride, silicon oxide, carbon doped silicon oxide, silicon carbo-nitride, and silicon oxynitride films are described herein. In yet another aspect, described herein is the use of the monoorganoaminodisilane precursors for depositing silicon-containing films in the fabrication of integrated circuit devices. In these or other aspects, the monoorganoaminodisilane precursors may be used for a variety of deposition processes, including but not limited to, atomic layer deposition (“ALD”), chemical vapor deposition (“CVD”), plasma enhanced chemical vapor deposition (“PECVD”), low pressure chemical vapor deposition (“LPCVD”), and atmospheric pressure chemical vapor deposition.

Several classes of compounds can be used as precursors for silicon-containing films. Examples of such compounds include silanes, chlorosilanes, polysilazanes, aminosilanes, and azidosilanes. Inert carrier gas or diluents such as, but not limited, helium, hydrogen, nitrogen, etc., are also used to deliver the precursors to the reaction chamber.

Low pressure chemical vapor deposition (LPCVD) processes are one of the more widely accepted methods used by semiconductor industry for the deposition of silicon-containing films. Using (LPCVD) with ammonia typically requires deposition temperatures of greater than 750° C. to obtain reasonable growth rates and uniformities. Higher deposition temperatures are typically employed to provide improved film properties. One of the more common industry methods to grow silicon nitride or other silicon-containing films is through low pressure chemical vapor deposition in a hot wall reactor at temperatures >750° C. using the precursors silane, dichlorosilane, and/or ammonia. However, there are several drawbacks using this method. For example, certain precursors, such as silane are pyrophoric. This may present problems in handling and usage. Also, films deposited from silane and dichlorosilane may contain certain impurities. For example, films deposited using dichlorosilane may contain certain impurities, such as chlorine and ammonium chloride, which are formed as byproducts during the deposition process. Films deposited using silane may contain hydrogen.

Precursors that are used in depositing silicon nitride films such as BTBAS and chlorosilanes generally deposit the films at temperatures greater than 550° C. The trend of miniaturization of semiconductor devices and low thermal budget requires lower process temperature and higher deposition rate. The temperature, at which the silicon films are deposited, should decrease in order to prevent ion diffusion in the lattice, particularly for those substrates comprising metallization layers and on many Group III-V and II-VI devices. Accordingly, there is a need in the art to provide precursors for the deposition of silicon-containing films, such as silicon oxide, carbon doped silicon oxide, silicon oxynitride, or silicon nitride films that are sufficiently chemically reactive to allow deposition via CVD, ALD or other processes at temperatures of 550° C. or below or even at room temperature.

The reference entitled “Disilanyl-amines—Compounds Comprising the Structure Unit Si—Si—N, as Single-Source Precursors for Plasma-Enhanced Chemical Vapor Deposition (PE-CVD) of Silicon Nitride”, Schuh et al., Zeitschrift Für Anorganische and Allgemeine Chemie, 619 (1993), pp. 1347-52 describes potential single-source precursors for PECVD of silicon nitride films wherein the precursors have the structural unit Si—Si—N such as (Et₂N)₂HSi—SiH₃, (Et₂N)₂HSi—SiH(NEt₂)₂[(i-Pr)₂N]H₂Si—SiH₃ and [(i-Pr)₂N]H₂Si—SiH₂[N(i-Pr)₂]. The precursor 1,2-bis(di-i-propylamino)disilane (BIPADS) was used for the PECVD deposition of silicon nitride films. The resulting films from the BIPADS precursor exhibited refractive indices ranging from 1.631-1.814 and had low carbon and very low oxygen contents but high (Si-bound) hydrogen contents.

The reference entitled “1,2-Disilanediyl Bis(triflate), F₃CSO₃—SiH₂—SiH₂—O₃SCF₃, as the Key Intermediate for a Facile Preparation of Open-Chain and Cyclic 1,1- and 1,2-Diaminodisilanes”, Sölder et al., Inorganic Chemistry, 36 (1997), pp. 1758-63 describes high yield syntheses for several open-chain and cyclic diaminodisilanes with fully hydrogenated Si linkages.

U.S. Pat. No. 5,660,895 describes the deposition of high-quality SiO₂ films at low temperatures in a PECVD process using disilane (Si₂H₆) and nitrous oxide.

U.S. Pat. Nos. 7,019,159 and 7,064,083 describe a composition and method of preparing silane compounds or hexakis(monohydrocarbylamino)disilanes that are free of chlorine and have the formula: ((R)HN)₃—Si—Si—(NH(R))₃ wherein R independently represents a C₁ to C₄ hydrocarbyl. The hexakis(monohydrocarbylamino)disilane precursors are used for the deposition of silicon nitride or silicon oxynitride films.

U.S. Pat. No. 8,153,832 describes pentakis(dimethylamino)disilane compounds having the formula: Si₂(NMe₂)₅Y where Y is selected from the group consisting of H, Cl, or an amino group and its use for manufacturing gate silicon-containing films or etch-stop silicon-containing films of SiN or SiON.

U.S. Publ. No. 2009/0209081 A describes methods for depositing silicon dioxide containing thin films on a substrate using hexakis(monoalkylamino)disilane such as hexakis(ethylamino)disilane as silicon source and ozone as oxidant. The growth rate was about 1.1 Å/cycle.

U.S. Pat. No. 7,077,904 describes methods for depositing silicon dioxide containing thin films on a substrate using hexachlorodisilane as silicon source and water as oxidant in presence of catalyst such as pyridine. The growth rates were in the range from 2.6 to 0.6 Å/cycle at substrate temperatures from 50 to 140° C.

U.S. Publ. No. 2013/0109155 describes a method of forming a seed layer for a thin film using an aminosilane based gas having two Si atoms such as hexakisethylaminodisilane (Cl₂H₃₆N₆Si₂). Other aminosilanes having the following formulas may also be used: (1) (R1R2)N)ₙSi₂H₆-n-m(R3)m . . . n: the number of amino groups, m: the number of alkyl groups or (2) (R1)NH)nSi₂H₆-n-m(R3)m . . . n: the number of amino groups, m: the number of alkyl groups. In formulas (1) and (2), R1, R2, R3=CH₃, C₂H₅, C₃H₇, R1=R2=R3, or may not be the same as each other, n=an integer ranging from 1 to 6 and m=0, and 1 to 5.

U.S. Pat. Nos. 7,446,217; 7,531,679; 7,713,346; 7,786,320; 7,887,883; and 7,910,765 describe silane precursors that comprise at least one disilane derivative that is fully substituted with alkylamino and/or dialkylamino functional groups. Besides the foregoing, there have been a few monodialkylaminodisilanes reported in the art such as dimethylaminodisilane (CAS#14396-26-0P), diethylaminodisilane (CAS#132905-0-5), and di-iso-propylaminodisilane (CAS#151625-25-1).

IPCOM000169457D “new unsymmetrical disilane compounds and their properties as precursors for silicon carbonitride thin film.” IP.com Journal. This discloses unknown unsymmetrical disilanes and their use for silicon carbonitride deposition at extra low temperature. Some unknown unsymmetrical disilanes compounds Me₃SiSi(NR¹R²)₃ (Ri being H, methyl, ethyl) have been synthesized and have been assessed as precursors for silicon carbonitride thin film formation.

Despite these developments, there is still a need for a process for forming a silicon oxide or carbon doped silicon oxide film having at least one or more of the following attributes: a density of about 2.1 g/cc or greater, a growth rate of 2.0 Å/cycle or greater, low chemical impurity, and/or high conformality in a thermal atomic layer deposition, a plasma enhanced atomic layer deposition (ALD) process or a plasma enhanced ALD-like process using cheaper, reactive, and more stable silicon precursor compounds.

### BRIEF SUMMARY OF THE INVENTION

Described herein are monoorganoaminodisilane precursors having only one organoamino group connected to an Si—H₂ group, and one Si—Si bond, compositions comprising same, and methods using same for forming films comprising silicon, such as, but not limited to, amorphous silicon, crystalline silicon, silicon oxide, carbon doped silicon oxide, silicon nitride, silicon oxynitride, silicon carbide, silicon carbonitride, and combinations thereof onto at least a portion of a substrate. In addition, described herein is a composition comprising a monoorganoaminodisilane described herein wherein the monoorganoaminodisilane is substantially free of at least one selected from the amines, halides, higher molecular weight species, and trace metals. In these or other embodiments, the composition may further comprise a solvent. Also disclosed herein are the methods to form films or coatings comprising silicon on an object to be processed, such as, for example, a semiconductor wafer. In one embodiment of the method described herein, a film comprising silicon and oxygen is deposited onto a substrate using a monoorganoaminodisilane precursor and an oxygen-containing source in a deposition chamber under conditions for generating a silicon oxide, carbon doped silicon oxide film on the substrate. In another embodiment of the method described herein, a film comprising silicon and nitrogen is deposited onto a substrate using a monoorganoaminodisilane precursor and a nitrogen containing precursor in a deposition chamber under conditions for generating a silicon nitride film on the substrate. In a further embodiment, the monoorganoaminodisilane precursors described herein can also be used a dopant for metal containing films, such as but not limited to, metal oxide films or metal nitride films. In the compositions and methods described herein, an monoorganoaminodisilane having the formula described herein is employed as at least one of the silicon containing precursors.

In one aspect, the monoorganoaminodisilane precursor described herein comprises at least one monoorganoaminodisilane precursor comprising only one organoamino group connected to an Si—H₂ group and one Si—Si bond represented by the following Formula I below:

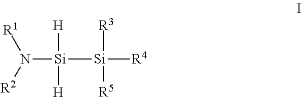

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; R³⁻⁵ are each independently selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen. In certain embodiments of Formula I, R¹ and R² are linked together to form a ring. In one particular embodiment, R¹ and R² are selected from a linear or a branched C₃ to C₆ alkyl group and are linked to form a cyclic ring. In alternative embodiments of Formula I, R¹ and R² are not linked together to form a ring. In certain embodiments of Formula I, R¹ and R² are the same with the proviso that they cannot both be iso-propyl. In other embodiments, R¹ and R² are different.

In another aspect, there is provided a composition comprising: (a) at least one monoorganoaminodisilane precursor comprising only one organoamino group connected to an Si—H₂ group and one Si—Si bond represented by the following Formula I below:

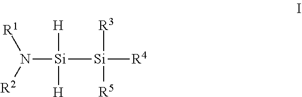

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and (b) a solvent. In certain embodiments of the composition described herein, exemplary solvents can include, without limitation, ether, tertiary amine, alkyl hydrocarbon, aromatic hydrocarbon, tertiary aminoether, and combinations thereof. In certain embodiments, the difference between the boiling point of the monoorganoaminodisilane and the boiling point of the solvent is 40° C. or less.

In another aspect, there is provided a method for forming a silicon-containing film on at least one surface of a substrate comprising:
providing the at least one surface of the substrate in a reaction chamber; and forming the silicon-containing film on the at least one surface by a deposition process chosen from a chemical vapor deposition process and an atomic layer deposition process using at least one monoorganoaminodisilane precursor comprising only one organoamino group connected to an Si—H₂ group and one Si—Si bond represented by the following Formula I below:

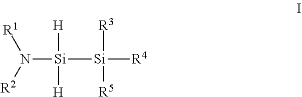

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen. In certain embodiments, R¹ and R² are the same. In other embodiments, R¹ and R² are different. In the foregoing or other embodiments, R¹ and R² can be linked together to form a ring. In further embodiments, R¹ and R² are not linked together to form a ring.

In another aspect, there is provided a method of forming a silicon oxide, carbon doped silicon oxide film via an atomic layer deposition process or ALD-like process, the method comprising the steps of:
a. providing a substrate in a reactor;
b. introducing into the reactor at least one monoorganoaminodisilane precursor comprising only one organoamino group connected to an Si—H₂ group and one Si—Si bond represented by the following Formula I below:

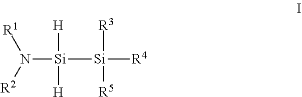

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group with the proviso that R³⁻⁵ cannot be all hydrogen;
c. purging the reactor with a purge gas;
d. introducing an oxygen-containing source into the reactor; and
e. purging the reactor with a purge gas; wherein steps b through e are repeated until a desired thickness of the film is obtained. In certain embodiments, R¹ and R² are the same. In other embodiments, R¹ and R² are different. In the foregoing or other embodiments, R¹ and R² can be linked together to form a ring. In the yet further embodiments, R¹ and R² are not linked together to form a ring.

In a further aspect, there is provided a method of forming a film selected from a silicon oxide film and a carbon doped silicon oxide film onto at least a surface of a substrate using a CVD process comprising:
a. providing a substrate in a reactor;
b. introducing into the reactor at least one monoorganoaminodisilane precursor comprising only one organoamino group connected to an Si—H₂ group and one Si—Si bond represented by the following Formula I below:

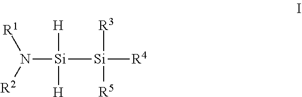

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group with the proviso that R³⁻⁵ cannot be all hydrogen; and
c. providing an oxygen-containing source to deposit the film onto the at least one surface. In certain embodiments of the method, R¹ and R² are the same. In some other embodiments, R¹ and R² are different. In other embodiments, R¹ and R² can be linked together to form a ring. In the yet further embodiments, R¹ and R² are not linked together to form a ring.

In another aspect, there is provided a method of forming a silicon nitride film via an atomic layer deposition process, the method comprising the steps of:
a. providing a substrate in a reactor;
b. introducing into the reactor an at least one monoorganoaminodisilane precursor comprising only one organoamino group connected to an Si—H₂ group and one Si—Si bond represented by the following Formula I below:

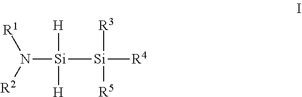

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group with the proviso that R³⁻⁵ cannot be all hydrogen;
c. purging the reactor with a purge gas;
d. introducing a nitrogen-containing source into the reactor; and
e. purging the reactor with a purge gas, wherein steps b through e are repeated until a desired thickness of the silicon nitride film is obtained. In certain embodiments, R¹ and R² in Formula I are the same. In other embodiments, R¹ and R² are different. In the foregoing or other embodiments, R¹ and R² can be linked together to form a ring. In a further embodiment, R¹ and R² are not linked together to form a ring.

In a further aspect, there is provided a method of forming a silicon nitride film onto at least a surface of a substrate using a CVD process comprising:
a. providing a substrate in a reactor;
b. introducing into the reactor at least one monoorganoaminodisilane precursor comprising only one organoamino group connected to an Si—H₂ group and one Si—Si bond represented by the following Formula I below:

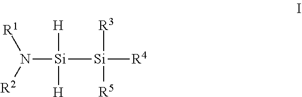

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
c. providing a nitrogen-containing source wherein the at least one monoorganoaminodisilane precursor and the nitrogen-containing source react to deposit the film onto the at least one surface. In some embodiments, R¹ and R² are the same. In other embodiments, R¹ and R² are different. In yet other embodiments, R¹ and R² can be linked together to form a ring. In the yet further embodiments, R¹ and R² are not linked together to form a ring.

In a further embodiment of the method described herein, the process is depositing an amorphous or a crystalline silicon film. In this embodiment, the method comprises:
placing one or more substrates into a reactor which is heated to one or more temperatures ranging from ambient temperature to about 700° C.;
introducing at least one monoorganoaminodisilane precursor comprising only one organoamino group connected to an Si—H₂ group and one Si—Si bond represented by the following Formula I below:

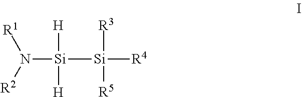

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
providing a reducing agent source into the reactor to at least partially react with the at least one monoorganoaminodisilane precursor and deposit a silicon-containing film onto the one or more substrates. The reducing agent is selected from the group consisting of hydrogen, hydrogen plasma, and hydrogen chloride. In certain embodiments of the CVD method, the reactor is maintained at a pressure ranging from 10 mTorr to 760 Torr during the introducing step. The above steps define one cycle for the method described herein, and the cycle of steps can be repeated until the desired thickness of a film is obtained. In some embodiments, R¹ and R² are the same. In other embodiments, R¹ and R² are different. In certain embodiments, R¹ and R² can be linked together to form a ring. In the yet further embodiments, R¹ and R² are not linked together to form a ring.

In another aspect, there is provided a method of depositing an amorphous or a crystalline silicon film via an atomic layer deposition or cyclic chemical vapor deposition process, the method comprising the steps of:
a. providing a substrate in a reactor;
b. introducing into the reactor at least one monoorganoaminodisilane precursor comprising only one organoamino group connected to an Si—H₂ group and one Si—Si bond represented by the following Formula I below:

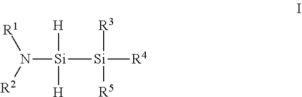

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen, and wherein step b is repeated until a desired thickness of the film is obtained. In certain embodiments, the thickness of the film can be 1 Å or greater, or 1 to 10,000 Å, or 1 to 1000 Å, or 1 to 100 Å.

In another aspect, a vessel for depositing a silicon-containing film comprising one or more monoorganoaminodisilane precursor having Formula I is described herein. In one particular embodiment, the vessel comprises at least one pressurizable vessel (preferably of stainless steel) fitted with the proper valves and fittings to allow the delivery of one or more precursors to the reactor for a CVD or an ALD process.

In another aspect, there is provided a composition only one organoamino group connected to an Si—H₂ group and one Si—Si bond represented by the following Formula I below:

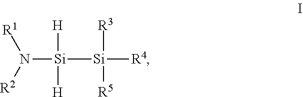

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen, wherein the composition is substantially free of halide ions. In one particular embodiment, the composition comprises an monoorganoaminodisilane having Formula I wherein R¹ and R² are both iso-propyl groups.

### DETAILED DESCRIPTION OF THE INVENTION

The monoorganoaminodisilanes described herein are used as precursors to form stoichiometric and non-stoichiometric silicon containing films such as, but not limited to, amorphous silicon, crystalline silicon, silicon oxide, silicon oxycarbide, silicon nitride, silicon oxynitride, and silicon oxycarbonitride. These precursors can also be used, for example, as dopants for metal containing films. The monoorganoaminodisilane precursors used in semi-conductor processes are typically high purity volatile liquid precursor chemical that are vaporized and delivered to a deposition chamber or reactor as a gas to deposit a silicon containing film via CVD or ALD processes for semiconductor devices. The selection of precursor materials for deposition depends upon the desired resultant silicon-containing material or film. For example, a precursor material may be chosen for its content of chemical elements, its stoichiometric ratios of the chemical elements, and/or the resultant silicon containing film or coating that are formed under CVD. The precursor material may also be chosen for various other characteristics such as cost, relatively low toxicity, handling characteristics, ability to maintain liquid phase at room temperature, volatility, molecular weight, and/or other considerations. In certain embodiments, the precursors described herein can be delivered to the reactor system by any number of means, preferably using a pressurizable stainless steel vessel fitted with the proper valves and fittings, to allow the delivery of liquid phase precursor to the deposition chamber or reactor.

The monoorganoaminodisilane precursors described herein exhibit a balance of reactivity and stability that makes them ideally suitable as CVD or ALD precursors in microelectronic device manufacturing processes. With regard to reactivity, the monoorganoaminodisilane in this invention has only one organoamino group which helps formation of Si—O—SH₂ linkage upon reacting the monoorganoaminodisilane precursors with hydroxyl surface during ALD process. The smaller footprint of SiH₂ allows more silicon-containing fragments with Si—Si bond being anchored, thus providing higher growth rate per cycle compared to conventional silicon precursors having only silicon atom. Certain precursors may have boiling points that are too high to be vaporized and delivered to the reactor to be deposited as a film on a substrate, so it is preferable to select smaller organoamino groups as well as smaller alkyl to provide precursors having boiling point of 250° C. or less, preferably boiling point of 200° C. or less. Having two or more organoamino groups as disclosed in prior art can increase the boiling point significantly, precursors having higher relative boiling points require that the delivery container and lines need to be heated at or above the boiling point of the precursor under a given vacuum to prevent condensation or particles from forming in the container, lines, or both. With regard to stability, other precursors may form silane (SiH₄) or disilane (Si₂H₆) as they degrade. Silane is pyrophoric at room temperature or it can spontaneously combust which presents safety and handling issues. Moreover, the formation of silane or disilane and other by-products decreases the purity level of the precursor and changes as small as 1-2% in chemical purity may be considered unacceptable for reliable semiconductor manufacture. In certain embodiments, the monoorganoaminodisilane precursors having Formula I described herein comprise 2% or less by weight, or 1% or less by weight, or 0.5% or less by weight of by-product (such as the corresponding bis-disilane byproduct) after being stored for a time period of 6 months or greater, or one year or greater which is indicative of being shelf stable. In addition to the foregoing advantages, in certain embodiments, such as for depositing a silicon oxide or silicon nitride or silicon film using an ALD, ALD-like, PEALD, or CCVD deposition method, the monoorganoaminodisilane precursor described herein may be able to deposit high density materials at relatively low deposition temperatures, e.g., 500° C. or less, or 400° C. or less, 300° C. or less, 200° C. or less, 100° C. or less, or 50° C. or less.

In one embodiment, described herein is a composition for forming a silicon-containing film comprising: an monoorganoaminodisilane having Formula I described herein and a solvent(s). Without intending to be bound by any particular theory, it is believed that composition described herein may provide one or more advantages compared to pure monoorganoaminodisilane. These advantages include: better usage of the monoorganoaminodisilane in semiconductor processes, better stability over long term storage, cleaner evaporation by flash vaporization, and/or overall more stable direct liquid injection (DLI) chemical vapor deposition process. The weight percentage of the monoorganoaminodisilane in the composition can range from 1 to 99% with the balance being solvent(s) wherein the solvent(s) does not react with the monoorganoaminodisilane and has a boiling point similar to the monoorganoaminodisilane. With regard to the latter, the difference between the boiling points of the monoorganoaminodisilane and solvent(s) in the composition is 40° C. or less, more preferably 20° C. or less, or 10° C. or less.

In one aspect, there is provided at least one monoorganoaminodisilane precursor comprising only one organoamino group connected to an Si—H₂ group and one Si—Si bond represented by the following Formula I below:

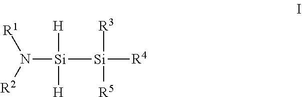

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen. In certain embodiments of Formula I, R¹ and R² are the same with the proviso that they cannot both be iso-propyl. In other embodiments, R¹ and R² are different. In one embodiment, R¹ and R² are selected from a linear or branched C₃ to C₆ alkyl group and are linked to form a cyclic ring. In the yet further embodiments, R¹ and R² are not linked together to form a ring.

In certain embodiments, the monoorganoaminodisilane precursor has the following Formula IA wherein R³⁻⁴ are independently selected from hydrogen, methyl and ethyl to provide precursors more suitable for delivery into vapor deposition chamber. Table 1 lists exemplary compounds having Formula IA.

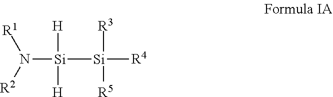

Exemplary compounds having Formula IA are listed below:

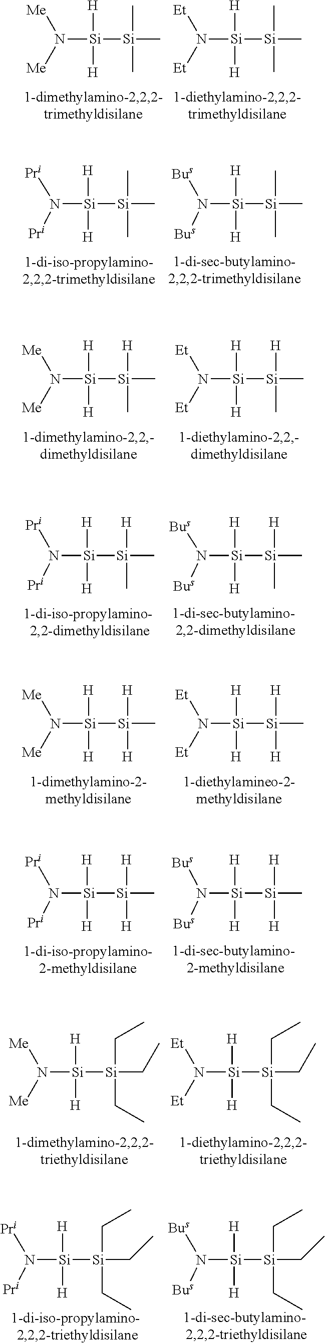

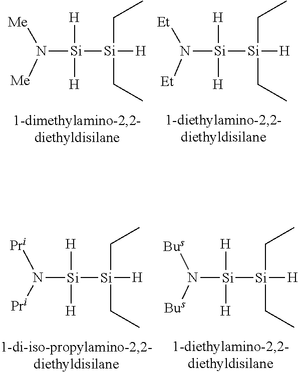

In other embodiments, the monoorganoaminodisilane precursor has the following Formula IB wherein R¹ and R² are selected from a linear or branched C₃ to C₆ alkyl group and are linked to form a cyclic ring.

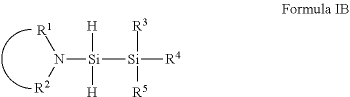

Exemplary compounds having Formula IB are listed below:

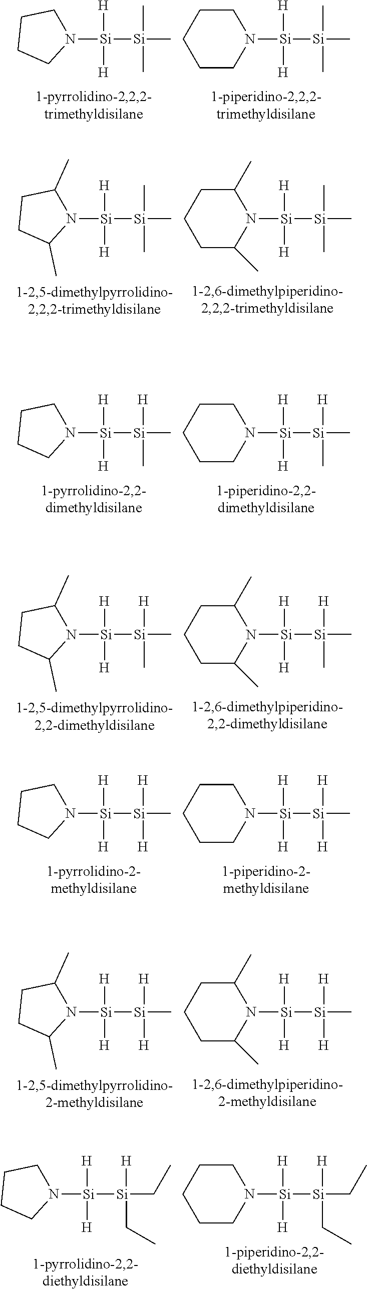

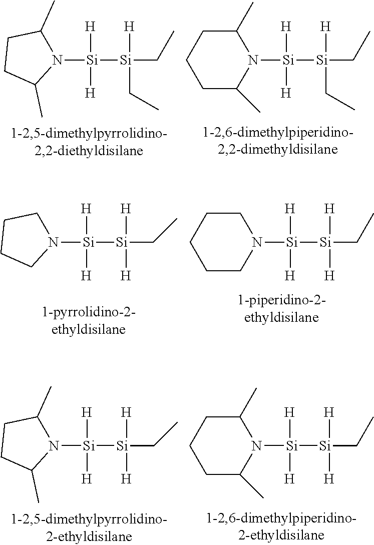

In the formulae and throughout the description, the term “alkyl” denotes a linear, or branched functional group having from 1 to 10 or 1 to 6 carbon atoms. Exemplary alkyl groups include, but are not limited to, methyl, ethyl, n-propyl, isopropyl, butyl, isobutyl, sec-butyl, tert-butyl, n-pentyl, iso-pentyl, tert-pentyl, n-hexyl, iso-hexyl, and neo-hexyl. In certain embodiments, the alkyl group may have one or more functional groups such as, but not limited to, an alkoxy group, a dialkylamino group or combinations thereof, attached thereto. In other embodiments, the alkyl group does not have one or more functional groups attached thereto.

In the formulae and throughout the description, the term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups.

In the formulae and throughout the description, the term “aryl” denotes an aromatic cyclic functional group having from 5 to 12 carbon atoms or from 6 to 10 carbon atoms. Exemplary aryl groups include, but are not limited to, phenyl, benzyl, chlorobenzyl, tolyl, and o-xylyl.

In the formulae and throughout the description, the term “alkenyl group” denotes a group which has one or more carbon-carbon double bonds and has from 3 to 10 or from 3 to 6 or from 3 to 4 carbon atoms.

In the formulae and throughout the description, the term “alkynyl group” denotes a group which has one or more carbon-carbon triple bonds and has from 3 to 10 or from 3 to 6 or from 3 to 4 carbon atoms.

In the formulae and throughout the description, the term “alkoxy” denotes an alkyl group which has is linked to an oxygen atom (e.g., R—O) and may have from 1 to 10, or from 1 to 6, or from 1 to 4 carbon atoms. Exemplary alkoxy groups include, but are not limited to, methoxy (—OCH₃), ethoxy(-OCH₂CH₃), n-propoxy (—OCH₂CH₂CH₃), and iso-propoxy (—OCHMe2).

In the formulae and throughout the description, the term “organoamino group” denotes a group which has two alkyl groups attached to a nitrogen atom and has from 1 to 10 or from 2 to 6 or from 2 to 4 carbon atoms. Exemplary organoamino groups include, but limited to, dimethylamino, diethylamino, ethylmethylamino, di-n-propylamino, di-iso-propylamino, di-n-butylamino, di-iso-butylamino di-sec-butylamino, tert-butylamino.

The term “electron withdrawing group” as used herein describes an atom or group thereof that acts to draw electrons away from the Si—N bond. Examples of suitable electron withdrawing groups or substituents include, but are not limited to, nitriles (CN). In certain embodiments, electron withdrawing substituent can be adjacent to or proximal to N in any one of Formula I. Further non-limiting examples of an electron withdrawing group includes F, Cl, Br, I, CN, NO₂, RSO, and/or RSO₂ wherein R can be a 01 to C₁₀ alkyl group such as, but not limited to, a methyl group or another group.

In certain embodiments, one or more of the alkyl group, alkenyl group, alkynyl group, alkoxy group, dialkylamino group, aryl group, and/or electron withdrawing group in Formula I may be substituted or have one or more atoms or group of atoms substituted in place of, for example, a hydrogen atom. Exemplary substituents include, but are not limited to, oxygen, sulfur, halogen atoms (e.g., F, Cl, I, or Br), nitrogen, and phosphorous. In other embodiments, one or more of the alkyl group, alkenyl group, alkynyl group, alkoxy group, dialkylamino aryl group, and/or electron withdrawing group in In certain embodiments, R¹ and R² are linked in Formula I to form a ring structure. In these embodiments, R² is not hydrogen. For example, in an embodiment where R¹ and R² are linked together to form a ring, R² may include a bond (instead of a hydrogen substituent) for linking to R¹. Thus, in this particular embodiment, R² may be selected from for example, a C₁ to C₁₀ alkyl moiety, a C₃ to C₁₀ alkenyl moiety or a linear or branched C₃ to C₁₀ alkynyl moiety. In these or other embodiments, the ring structure can be unsaturated such as, for example, a cyclic alkyl ring, or saturated, for example, an aryl ring. Further, in these or other embodiments, the ring structure can also be substituted or substituted. In one particular embodiment, the monoorganoaminodisilane comprises an aliphatic, substituted ring such as a heteratomic cyclic functional group having from 5 to 10 carbon atoms and at least one nitrogen atom. Exemplary of these particular embodiments include, but are not limited to, 1,2-bis(pyrrolidino)disilane wherein R¹=propyl and R²=Me, 1,2-bis(piperidino)disilane wherein R¹=propyl and R²=Et, 2,6-dimethylpiperidinodisilane wherein R¹=iso-propyl and R²=sec-butyl, and 2,5-dimethylpyrrolidinodilane wherein R¹=R²=iso-propyl.

In certain embodiments, the at least one monoorganoaminodisilane precursor having Formula I has one or more substituents comprising oxygen or nitrogen atoms. In this or other embodiments, substituents R¹ and R² are linked via an oxygen or a nitrogen atom in Formula I to form a ring structure.

Without intending to be bound by any particular theory, it is believed that monoorganoaminodisilane precursors such as those monoorganoaminodisilanes having Formula I described herein comprising one Si—N bond, one Si—Si bond and one SiH₂ group are advantageous over known monoorganoaminodisilane precursors containing more than one Si—N bonds and Si—Si bonds or only Si—Cl and Si—Si bonds. In this regard, it is believed that the monoorganoaminodisilanes described herein having only two Si—H groups, one —Si—N bond and one Si—Si bond make them more reactive than other monoorganoaminodisilane precursors, allowing deposition temperatures to be lower than other known monoorganoaminodisilanes, such as, for example, hexachlorodisilane. It is believed that the unique structures of the Formula 1 precursors described herein allow for deposition temperatures of 400° C. or less, 300° C. or less, 200° C. or less, 100° C. or less, or 25° C. or less.

In certain embodiments, the monoorganoaminodisilanes having Formula I can be prepared by reacting 1,1,1-trihalido-2,2,2-trialkyldisilane, or 1,1,1-trihalido-2,2-dialkyldisilane or 1,1,1-trihalido-2-alkyldisilane with an amine in an organic solvent or solvent mixture, followed by reaction with metal hydride to convert Si—X into Si—H groups.

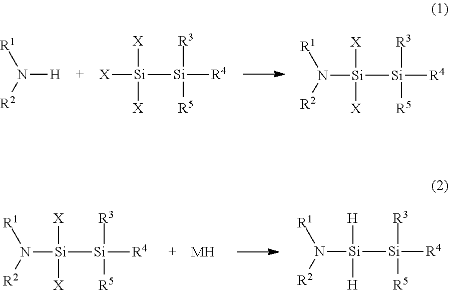

In Equation (1) and (2) R¹ and R² are the same as in the substituents described in Formula I and X is selected from the group consisting of chloride, bromide, and iodide. The following Equation (1) and (2) provide a non-limiting example of a reaction schemes or synthesis route which may be used to make the monoorganoaminodisilanes having Formula I as described herein. The reaction in Equation (1) and (2) can be conducted with (e.g., in the presence of) or without (e.g., in the absence of) organic solvents. In embodiments wherein an organic solvent is used, examples of suitable organic solvents include, but are not limited to, hydrocarbon such as hexanes, octane, toluene, and ethers such as diethylether and tetrahydrofuran (THF). In these or other embodiments, the reaction temperature is in the range of from about −70° C. to the boiling point of the solvent employed if a solvent is used. The resulting monoorganoaminodisilane can be purified, for example, via vacuum distillation after removing all by-products as well as any solvent(s) if present.

Equations (1) and (2) are one synthetic route to make the monoorganoaminodisilanes having Formula I. Other synthetic routes such as equation (3) may be also employed to make these monoorganoaminodisilanes via dehydro-coupling reaction between monoorganoaminosilane with trialkylsilane having one Si—H, or dialkylsilane having two Si—H groups (i.e. R³ is hydrogen in equation (3)) or alkylsilane (i.e. R³ and R⁴ are hydrogen in equation (3)) having three Si—H groups with primary or secondary amine in presence of catalyst.

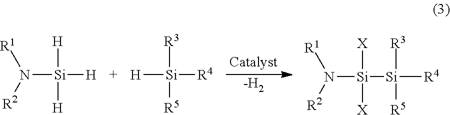

The catalyst employed in the method of the present invention is one that promotes the formation of a silicon-silicon bond. Exemplary catalysts that can be used with the method described herein include, but are not limited to the following: alkaline earth metal catalysts; halide-free main group, transition metal, lanthanide, and actinide catalysts; and halide-containing main group, transition metal, lanthanide, and actinide catalysts.

Exemplary alkaline earth metal catalysts include but are not limited to the following: Mg[N(SiMe₃)₂]₂, To^{M}MgMe [To^{M}=tris(4,4-dimethyl-2-oxazolinyl)phenylborate], To^{M}Mg—H, To^{M}Mg—NR₂ (R═H, alkyl, aryl) Ca[N(SiMe₃)₂]₂, [(dipp-nacnac)CaX(THF)]2 (dipp-nacnac=CH[(CMe)(2,6-ⁱPr₂—C₆H₃N)]₂; X═H, alkyl, carbosilyl, organoamino), Ca(CH₂Ph)₂, Ca(C₃H₅)₂, Ca(α-Me₃Si-2-(Me₂N)-benzyl)₂(THF)₂, Ca(9-(Me₃Si)-fluorenyl)(α-Me₃Si-2-(Me₂N)-benzyl)(THF), [(Me₃TACD)₃Ca₃(μ³-H)₂]+(Me₃TACD=Me₃[12]aneN₄), Ca(η²-Ph₂CNPh)(hmpa)₃ (hmpa=hexamethylphosphoramide), Sr[N(SiMe₃)₂]₂, and other M²⁺ alkaline earth metal-amide, -imine, -alkyl, -hydride, and -carbosilyl complexes (M=Ca, Mg, Sr, Ba).

Exemplary halide-free, main group, transition metal, lanthanide, and actinide catalysts include but are not limited to the following: 1,3-di-iso-propyl-4,5-dimethylimidazol-2-ylidene, 2,2′-bipyridyl, phenanthroline, B(C₆F₅)₃, BR₃ (R=linear, branched, or cyclic C₁ to C₁₀ alkyl group, a C₅ to C₁₀ aryl group, or a C₁ to C₁₀ alkoxy group), AIR₃ (R=linear, branched, or cyclic C₁ to C₁₀ alkyl group, a C₅ to C₁₀ aryl group, or a C₁ to C₁₀ alkoxy group), (C₅H₅)₂TiR₂ (R=alkyl, H, alkoxy, organoamino, carbosilyl), (C₅H₅)₂Ti(OAr)₂ [Ar=(2,6-(ⁱPr)₂C₆H₃)], (C₅H₅)₂Ti(SiHRR′)PMe₃ (wherein R, R′ are each independently selected from H, Me, Ph), TiMe₂(dmpe)₂ (dmpe=1,2-bis(dimethylphosphino)ethane), bis(benzene)chromium(0), Cr(CO)₆, Mn₂(CO)₁₂, Fe(CO)₅, Fe₃(CO)₁₂, (C₅H₅)Fe(CO)₂Me, Co₂(CO)₈, Ni(II) acetate, Nickel(II) acetylacetonate, Ni(cyclooctadiene)₂, [(dippe)Ni(μ-H)]₂ (dippe=1,2-bis(di-iso-propylphosphino)ethane), (R-indenyl)Ni(PR′₃)Me (R=1-ⁱPr, 1-SiMe₃, 1,3-(SiMe₃)₂; R′=Me,Ph), [{Ni(η-CH₂:CHSiMe₂)₂O}₂{μ-(η-CH₂:CHSiMe₂)₂O}], Cu(I) acetate, CuH, [tris(4,4-dimethyl-2-oxazolinyl)phenylborate]ZnH, (C₅H₅)₂ZrR₂ (R=alkyl, H, alkoxy, organoamino, carbosilyl), Ru₃(CO)₁₂, [(Et₃P)Ru(2,6-dimesitylthiophenolate)][B[3,5-(CF₃)₂C₆H₃]₄], [(C₅Me₅)Ru(R₃P)ₓ(NCMe)₃₋ₓ]+(wherein R is selected from a linear, branched, or cyclic C₁ to C₁₀ alkyl group and a C₅ to C₁₀ aryl group; x=0, 1, 2, 3), Rh₆(CO)₁₆, tris(triphenylphosphine)rhodium(I)carbonyl hydride, Rh₂H₂(CO)₂(dppm)₂ (dppm=bis(diphenylphosphino)methane, Rh₂(μ-SiRH)₂(CO)₂(dppm)₂ (R=Ph, Et, O₆H₁₃), Pd/C, tris(dibenzylideneacetone)dipalladium(0), tetrakis(triphenylphosphine)palladium(0), Pd(II) acetate, (C₅H₅)₂SmH, (C₅Me₅)₂SmH, (THF)₂Yb[N(SiMe₃)₂]₂, (NHC)Yb(N(SiMe₃)₂)₂ [NHC=1,3-bis(2,4,6-trimethylphenyl) imidazol-2-ylidene)], Yb(η²-Ph₂CNPh)(hmpa)₃ (hmpa=hexamethylphosphoramide), W(CO)₆, Re₂(CO)₁₀, OS₃(CO)₁₂, Ir₄(CO)₁₂, (acetylacetonato)dicarbonyliridium(I), Ir(Me)₂(C₅Me₅)L (L=PMe₃, PPh₃), [Ir(cyclooctadiene)OMe]2, PtO₂ (Adams's catalyst), Pt/C, Platinum(0)-1,3-divinyl-1,1,3,3-tetramethyldisiloxane (Karstedt's catalyst), bis(tri-tert-butylphosphine)platinum(0), Pt(cyclooctadiene)₂, [(Me₃Si)₂N]₃U][BPh₄], [(Et₂N)₃U][BPh4], and other halide-free Mⁿ⁺ complexes (M=Sc, Ti, V, Cr, Mn, Fe, Co, Ni, Cu, Zn, Y, Zr, Nb, Mo, Ru, Rh, Pd, La, Ce, Pr, Nd, Pm, Sm, Eu, Gd, Tb, Dy, Ho, Er, Tm, Yb, Lu, Hf, Ta, W, Re, Os, Ir, Pt, U; n=0, 1, 2, 3, 4, 5, 6).

Exemplary halide-containing, main group, transition metal, lanthanide, and actinide catalysts include but are not limited to the following: BX₃ (X═F, Cl, Br, I), BF₃.OEt₂, AlX₃ (X═F, Cl, Br, I), (C₅H₅)₂TiX₂ (X═F, Cl), [Mn(CO)₄Br]₂, NiCl₂, (C₅H₅)₂ZrX₂ (X═F, Cl), PdCl₂, PdI₂, CuCl, CuI, CuF₂, CuCl₂, CuBr₂, Cu(PPh₃)₃Cl, ZnCl₂, [(C₆H₆)RuX₂]₂ (X═Cl, Br, I), (Ph₃P)₃RhCl (Wilkinson's catalyst), [RhCl(cyclooctadiene)]2, di-μ-chloro-tetracarbonyldirhodium(I), bis(triphenylphosphine)rhodium(I) carbonyl chloride, NdI₂, SmI₂, DyI₂, (POCOP)IrHCl (POCOP=2,6-(R₂PO)₂C₆H₃; R=ⁱPr, ⁿBu, Me), H₂PtCl₆nH₂O (Speier's catalyst), PtCl₂, Pt(PPh₃)₂Cl₂, and other halide-containing Mⁿ⁺ complexes (M=Sc, Ti, V, Cr, Mn, Fe, Co, Ni, Cu, Zn, Y, Zr, Nb, Mo, Ru, Rh, Pd, La, Ce, Pr, Nd, Pm, Sm, Eu, Gd, Tb, Dy, Ho, Er, Tm, Yb, Lu, Hf, Ta, W, Re, Os, Ir, Pt, U; n=0, 1, 2, 3, 4, 5, 6).

The monoorganoaminodisilane precursors according to the present invention and compositions comprising the monoorganoaminodisilane precursors according to the present invention are preferably substantially free of halide ions. As used herein, the term “substantially free” as it relates to halide ions (or halides) such as, for example, chlorides (i.e. chloride-containing species such as HCl or silicon compounds having at least one Si—Cl bond) and fluorides, bromides, and iodides, means less than 5 ppm (by weight) measured by ICP-MS, preferably less than 3 ppm measured by ICP-MS, and more preferably less than 1 ppm measured by ICP-MS, and most preferably 0 ppm measured by ICP-MS. Chlorides are known to act as decomposition catalysts for the monoorganoaminodisilane precursors. Significant levels of chloride in the final product can cause the monoorganoaminodisilane to degrade. The gradual degradation of the monoorganoaminodisilane precursors may directly impact the film deposition process making it difficult for the semiconductor manufacturer to meet film specifications. In addition, the shelf-life or stability is negatively impacted by the higher degradation rate of the silicon precursor compounds thereby making it difficult to guarantee a 1-2 year shelf-life. Therefore, the accelerated decomposition of the monoorganoaminodisilane precursors presents safety and performance concerns related to the formation of these flammable and/or pyrophoric gaseous byproducts. The monoorganoaminodisilane precursors are preferably substantially free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “substantially free” as it relates to Li, Na, K, Mg, Ca, Al, Fe, Ni, Cr means less than 5 ppm (by weight), preferably less than 3 ppm, and more preferably less than 1 ppm, and most preferably 0.1 ppm as measured by ICP-MS. In some embodiments, the silicon precursor compounds having Formulae A or B are free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “free of” metal impurities as it relates to Li, Na, K, Mg, Ca, Al, Fe, Ni, Cr, noble metal such as volatile Ru or Pt complexes from ruthenium or platinum catalysts used in the synthesis, means less than 1 ppm, preferably 0.1 ppm (by weight) as measured by ICP-MS or other analytical method for measuring metals.

Compositions according to the present invention that are substantially free of halides can be achieved by (1) reducing or eliminating chloride sources during chemical synthesis, and/or (2) implementing an effective purification process to remove chloride from the crude product such that the final purified product is substantially free of chlorides. Chloride sources may be reduced during synthesis by using reagents that do not contain halides such as chlorodislanes, bromodisilanes, or iododislanes thereby avoiding the production of by-products that contain halide ions. In addition, the aforementioned reagents should be substantially free of chloride impurities such that the resulting crude product is substantially free of chloride impurities. In a similar manner, the synthesis should not use halide based solvents, catalysts, or solvents which contain unacceptably high levels of halide contamination. The crude product may also be treated by various purification methods to render the final product substantially free of halides such as chlorides. Such methods are well described in the prior art and, may include, but are not limited to, purification processes such as distillation, or adsorption. Distillation is commonly used to separate impurities from the desire product by exploiting differences in boiling point. Adsorption may also be used to take advantage of the differential adsorptive properties of the components to effect separation such that the final product is substantially free of halide. Adsorbents such as, for example, commercially available MgO—Al₂O₃ blends can be used to remove halides such as chloride.

The method used to form the silicon-containing films or coatings are deposition processes. Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the metal containing films are deposited via atomic layer deposition (ALD), plasma enhanced ALD (PEALD) or plasma enhanced cyclic CVD (PECCVD) process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator. In one embodiment, the silicon-containing film is deposited using an ALD process. In another embodiment, the silicon-containing film is deposited using a CCVD process. In a further embodiment, the silicon-containing film is deposited using a thermal CVD process. The term “reactor” as used herein, includes without limitation, reaction chamber or deposition chamber.

In certain embodiments, the method disclosed herein avoids pre-reaction of the precursors by using ALD or CCVD methods that separate the precursors prior to and/or during the introduction to the reactor. In this connection, deposition techniques such as ALD or CCVD processes are used to deposit the silicon-containing film. In one embodiment, the film is deposited via an ALD process by exposing the substrate surface alternatively to the one or more the silicon-containing precursor, oxygen-containing source, nitrogen-containing source, or other precursor or reagent. Film growth proceeds by self-limiting control of surface reaction, the pulse length of each precursor or reagent, and the deposition temperature. However, once the surface of the substrate is saturated, the film growth ceases.

In certain embodiments, the method described herein further comprises one or more additional silicon-containing precursors other than the monoorganoaminodisilane precursor having the above Formula I. Examples of additional silicon-containing precursors include, but are not limited to, monoaminosilane (e.g., di-iso-propylaminosilane, di-sec-butylaminosilane, phenylmethylaminosilane; organo-silicon compounds such as trisilylamine (TSA); monoaminosilane (di-iso-propylaminosilane, di-sec-butylaminosilane, phenylmethylaminosilane); siloxanes (e.g., hexamethyl disiloxane (HMDSO) and dimethyl siloxane (DMSO)); organosilanes (e.g., methylsilane, dimethylsilane, diethylsilane, vinyl trimethylsilane, trimethylsilane, tetramethylsilane, ethylsilane, disilylmethane, 2,4-disilapentane, 1,4-disilabutane, 2,5-disilahexane, 2,2-disilylpropane, 1,3,5-trisilacyclohexane and fluorinated derivatives of these compounds); phenyl-containing organo-silicon compounds (e.g., dimethylphenylsilane and diphenylmethylsilane); oxygen-containing organo-silicon compounds, e.g., dimethyldimethoxysilane; 1,3,5,7-tetramethylcyclotetrasiloxane; 1,1,3,3-tetramethyldisiloxane; 1,3,5,7-tetrasila-4-oxo-heptane; 2,4,6,8-tetrasila-3,7-dioxo-nonane; 2,2-dimethyl-2,4,6,8-tetrasila-3,7-dioxo-nonane; octamethylcyclotetrasiloxane; [1,3,5,7,9]-pentamethylcyclopentasiloxane; 1,3,5,7-tetrasila-2,6-dioxo-cyclooctane; hexamethylcyclotrisiloxane; 1,3-dimethyldisiloxane; 1,3,5,7,9-pentamethylcyclopentasiloxane; hexamethoxydisiloxane, and fluorinated derivatives of these compounds.

Depending upon the deposition method, in certain embodiments, the one or more silicon-containing precursors may be introduced into the reactor at a predetermined molar volume, or from about 0.1 to about 1000 micromoles. In this or other embodiments, the silicon-containing and/or monoorganoaminodisilane precursor may be introduced into the reactor for a predetermined time period. In certain embodiments, the time period ranges from about 0.001 to about 500 seconds.

In certain embodiments, the silicon-containing films deposited using the methods described herein are formed in the presence of oxygen using an oxygen-containing source, reagent or precursor comprising oxygen. An oxygen-containing source may be introduced into the reactor in the form of at least one oxygen-containing source and/or may be present incidentally in the other precursors used in the deposition process. Suitable oxygen-containing source gases may include, for example, water (H₂O) (e.g., deionized water, purifier water, and/or distilled water), oxygen (O₂), oxygen plasma, ozone (O₃), NO, N₂O, NO₂, carbon monoxide (CO), carbon dioxide (CO₂) and combinations thereof. In certain embodiments, the oxygen-containing source comprises an oxygen-containing source gas that is introduced into the reactor at a flow rate ranging from about 1 to about 2000 standard cubic centimeters (sccm) or from about 1 to about 1000 sccm. The oxygen-containing source can be introduced for a time that ranges from about 0.1 to about 100 seconds. In one particular embodiment, the oxygen-containing source comprises water having a temperature of 10° C. or greater. In embodiments wherein the film is deposited by an ALD or a cyclic CVD process, the precursor pulse can have a pulse duration that is greater than 0.01 seconds, and the oxygen-containing source can have a pulse duration that is less than 0.01 seconds, while the water pulse duration can have a pulse duration that is less than 0.01 seconds. In yet another embodiment, the purge duration between the pulses that can be as low as 0 seconds or is continuously pulsed without a purge in between. The oxygen-containing source or reagent is provided in a molecular amount less than a 1:1 ratio to the silicon precursor, so that at least some carbon is retained in the as deposited silicon-containing film.

In certain embodiments, the silicon-containing films comprise silicon and nitrogen. In these embodiments, the silicon-containing films deposited using the methods described herein are formed in the presence of nitrogen-containing source. A nitrogen-containing source may be introduced into the reactor in the form of at least one nitrogen-containing source and/or may be present incidentally in the other precursors used in the deposition process. Suitable nitrogen-containing source gases may include, for example, ammonia, hydrazine, monoalkylhydrazine, dialkylhydrazine, nitrogen, nitrogen/hydrogen, ammonia plasma, nitrogen plasma, nitrogen/hydrogen plasma, and mixture thereof. In certain embodiments, the nitrogen-containing source comprises an ammonia plasma or hydrogen/nitrogen plasma source gas that is introduced into the reactor at a flow rate ranging from about 1 to about 2000 standard cubic centimeters (sccm) or from about 1 to about 1000 sccm. The nitrogen-containing source can be introduced for a time that ranges from about 0.1 to about 100 seconds. In embodiments wherein the film is deposited by an ALD or a cyclic CVD process, the precursor pulse can have a pulse duration that is greater than 0.01 seconds, and the nitrogen-containing source can have a pulse duration that is less than 0.01 seconds, while the water pulse duration can have a pulse duration that is less than 0.01 seconds. In yet another embodiment, the purge duration between the pulses that can be as low as 0 seconds or is continuously pulsed without a purge in-between.

The deposition methods disclosed herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen-containing source, the nitrogen-containing source, and/or other precursors, source gases, and/or reagents may be performed by changing the time for supplying them to change the stoichiometric composition of the resulting silicon-containing film.

Energy is applied to the at least one of the precursor, nitrogen-containing source, reducing agent, other precursors or combination thereof to induce reaction and to form the silicon-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The monoorganoaminodisilane precursors and/or other silicon-containing precursors may be delivered to the reaction chamber such as a CVD or ALD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, Minn., to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

For those embodiments wherein the precursor(s) having Formula I is used in a composition comprising a solvent and an monoorganoaminodisilane precursor having Formula I described herein, the solvent or mixture thereof selected does not react with the monoorganoaminodisilane. The amount of solvent by weight percentage in the composition ranges from 0.5% by weight to 99.5% or from 10% by weight to 75%. In this or other embodiments, the solvent has a boiling point (b.p.) similar to the b.p. of the monoorganoaminodisilane of Formula I or the difference between the b.p. of the solvent and the b.p. of the organoaminosilane of Formula I is 40° C. or less, 30° C. or less, or 20° C. or less, or 10° C. Alternatively, the difference between the boiling points ranges from any one or more of the following end-points: 0, 10, 20, 30, or 40° C. Examples of suitable ranges of b.p. difference include without limitation, 0 to 40° C., 20° to 30° C., or 10° to 30° C. Examples of suitable solvents in the compositions include, but are not limited to, an ether (such as 1,4-dioxane, dibutyl ether), a tertiary amine (such as pyridine, 1-methylpiperidine, 1-ethylpiperidine, N,N′-Dimethylpiperazine, N,N,N′,N′-Tetramethylethylenediamine), a nitrile (such as benzonitrile), an alkyl hydrocarbon (such as octane, nonane, dodecane, ethylcyclohexane), an aromatic hydrocarbon (such as toluene, mesitylene), a tertiary aminoether (such as bis(2-dimethylaminoethyl) ether), or mixtures thereof.

In another embodiment, a vessel for depositing a silicon-containing film comprising one or more monoorganoaminodisilane precursor(s) having Formula I is described herein. In one particular embodiment, the vessel comprises at least one pressurizable vessel (preferably of stainless steel) fitted with the proper valves and fittings to allow the delivery of one or more precursors to the reactor for a CVD or an ALD process. In this or other embodiments, the monoorganoaminodisilane precursor having Formula I is provided in a pressurizable vessel comprised of stainless steel and the purity of the precursor is 98% by weight or greater or 99.5% or greater which is suitable for the majority of semiconductor applications. In certain embodiments, such vessels can also have means for mixing the precursors with one or more additional precursor if desired. In these or other embodiments, the contents of the vessel(s) can be premixed with an additional precursor. Alternatively, the monoorganoaminodisilane precursor and/or other precursor can be maintained in separate vessels or in a single vessel having separation means for maintaining the monoorganoaminodisilane precursor and other precursor separate during storage.

In one embodiment of the method described herein, a cyclic deposition process such as CCVD, ALD, or PEALD may be employed, wherein at least one silicon-containing precursor selected from an monoorganoaminodisilane precursor having the formula described herein and optionally a nitrogen-containing source such as, for example, ammonia, hydrazine, monoalkylhydrazine, dialkylhydrazine, nitrogen, nitrogen/hydrogen, ammonia plasma, nitrogen plasma, nitrogen/hydrogen plasma are employed.

In certain embodiments, the gas lines connecting from the precursor canisters to the reaction chamber are heated to one or more temperatures depending upon the process requirements and the container of the monoorganoaminodisilane precursor having the formula I described herein is kept at one or more temperatures for bubbling. In other embodiments, a solution comprising the at least one silicon-containing precursor having the formula described herein is injected into a vaporizer kept at one or more temperatures for direct liquid injection.

A flow of argon and/or other gas may be employed as a carrier gas to help deliver the vapor of the at least one monoorganoaminodisilane precursor to the reaction chamber during the precursor pulsing. In certain embodiments, the reaction chamber process pressure is about 10 Torr or less. In another embodiments, the reaction chamber process pressure is about 5 Torr or less.

In a typical ALD or CCVD process, a substrate such as, without limitation, a silicon oxide, carbon doped silicon oxide, flexible substrate, or metal nitride substrate is heated on a heater stage in a reaction chamber that is exposed to the silicon-containing precursor initially to allow the monoorganoaminodisilane to chemically adsorb onto the surface of the substrate. A purge gas such as nitrogen, argon, or other inert gas purges away unabsorbed excess monoorganoaminodisilane from the process chamber. After sufficient purging, an oxygen-containing source may be introduced into reaction chamber to react with the absorbed surface followed by another gas purge to remove reaction by-products from the chamber. The process cycle can be repeated to achieve the desired film thickness. In other embodiments, pumping under vacuum can be used to remove unabsorbed excess monoorganoaminodisilane from the process chamber, after sufficient evacuation under pumping, an oxygen-containing source may be introduced into reaction chamber to react with the absorbed surface followed by another pumping down purge to remove reaction by-products from the chamber. In yet another embodiment, the monoorganoaminodisilane and the oxygen-containing source can be co-flowed into reaction chamber to react on the substrate surface to deposit silicon oxide, carbon doped silicon oxide. In a certain embodiment of cyclic CVD, the purge step is not used.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

In another embodiment of the method disclosed herein, the films containing both silicon and nitrogen are formed using an ALD, PEALD, CCVD or PECCVD deposition method that comprises the steps of:
a. providing a substrate in an ALD reactor;
b. introducing into the ALD reactor at least one monoorganoaminodisilane precursor comprising only one organoamino group connected to an Si—H₂ group and one Si—Si bond represented by the following Formula I below:

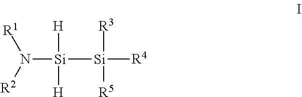

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen, optionally wherein R¹ and R² are linked together to form a ring selected from a substituted or unsubstituted aromatic ring or a substituted or unsubstituted aliphatic ring;
c. chemisorbing the at least one monoorganoaminodisilane precursor onto a substrate;
d. purging away the unreacted at least one monoorganoaminodisilane precursor using a purge gas;
e. providing a nitrogen-containing source to the monoorganoaminodisilane precursor onto the heated substrate to react with the sorbed at least one monoorganoaminodisilane precursor; and
f. optionally purging or pumping away any unreacted nitrogen-containing source.

In another aspect, there is provided a method of forming a film selected from a silicon oxide and a carbon doped silicon oxide film via a PEALD or a PECCVD deposition process, the method comprising the steps of:
a. providing a substrate in a reactor;
b. introducing into the reactor oxygen along with at least one monoorganoaminodisilane precursor comprising only one organoamino group connected to an Si—H₂ group and one Si—Si bond represented by the following Formula I below:

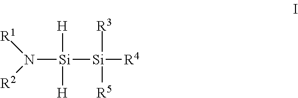

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen;
c. purging the reactor with a purge gas along with oxygen;
d. applying RF plasma;
e. purging the reactor with a purge gas or pumping the reactor to remove unreacted monoorganoaminodisilane and any by-products, wherein steps b through e are repeated until a desired thickness of the film is obtained.

In another embodiment of the method disclosed herein, the silicon-containing films is formed using a ALD deposition method that comprises the steps of:
a. providing a substrate in a reactor;
b. introducing into the reactor at least one monoorganoaminodisilane precursor comprising only one organoamino group connected to an Si—H₂ group and one Si—Si bond represented by the following Formula I below:

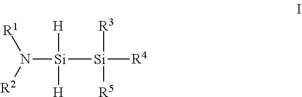

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen;
c. chemisorbing the at least one monoorganoaminodisilane precursor onto a substrate;
d. purging away the unreacted at least one monoorganoaminodisilane precursor using a purge gas;
e. providing an oxygen-containing source to the monoorganoaminodisilane precursor onto the heated substrate to react with the sorbed at least one monoorganoaminodisilane precursor; and
f. optionally purging or pumping away any unreacted oxygen-containing source.

In another aspect, there is provided a method of forming a silicon nitride or silicon carbonitride film via PEALD or PECCVD process, the method comprising the steps of:
a. providing a substrate in a reactor;
b. introducing into the reactor a nitrogen-containing source and at least one monoorganoaminodisilane precursor comprising only one organoamino group connected to an Si—H₂ group and one Si—Si bond represented by the following Formula I below:

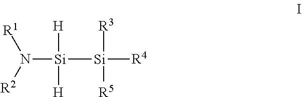

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen;
c. purging the reactor with a purge gas along with the nitrogen-containing source;
d. applying RF plasma; and
e. purging the reactor with a purge gas or pumping the reactor to remove unreacted monoorganoaminodisilane and any by-products, wherein steps b through e are repeated until a desired thickness of the film is obtained.

The above steps define one cycle for the method described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the precursors and oxygen-containing source may be performed by varying the duration of the time for supplying them to change the stoichiometric composition of the resulting silicon-containing film, although always using oxygen in less than a stoichiometric amount relative to the available silicon.

For multi-component silicon-containing films, other precursors such as silicon-containing precursors, nitrogen-containing precursors, reducing agents, or other reagents can be alternately introduced into the reactor chamber.

In a further embodiment of the method described herein, the silicon-containing film is deposited using a thermal CVD process. In this embodiment, the method comprises:
a. placing one or more substrates into a reactor which is heated to one or more temperatures ranging from ambient temperature to about 700° C.;
b. introducing at least one monoorganoaminodisilane precursor comprising only one organoamino group connected to an Si—H₂ group and one Si—Si bond represented by the following Formula I below:

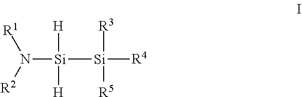

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
c. providing an oxygen-containing source into the reactor to at least partially react with the at least one monoorganoaminodisilane precursor and deposit a silicon-containing film onto the one or more substrates. In certain embodiments of the CVD method, the reactor is maintained at a pressure ranging from 10 mTorr to 760 Torr during the introducing step. The above steps define one cycle for the method described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the precursors and oxygen-containing source may be performed by varying the duration of the time for supplying them to change the stoichiometric composition of the resulting silicon-containing film, although always using oxygen in less than a stoichiometric amount relative to the available silicon.

In a further embodiment of the method described herein, an amorphous or crystalline silicon film is deposited using the Formula I precursor described herein. In this embodiment, the method comprises:
a. placing one or more substrates into a reactor which is heated to a one or more temperatures ranging from ambient temperature to about 700° C.;
b. introducing at least one monoorganoaminodisilane precursor comprising only one organoamino group connected to an Si—H₂ group and one Si—Si bond represented by the following Formula I below:

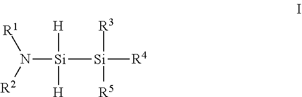

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
c. providing a reducing agent source into the reactor to at least partially react with the at least one monoorganoaminodisilane precursor and deposit a silicon-containing film onto the one or more substrates. The reducing agent is selected from the group consisting of hydrogen, hydrogen plasma, hydrogen chloride. In certain embodiments of the CVD method, the reactor is maintained at a pressure ranging from 10 mTorr to 760 Torr during the introducing step. The above steps define one cycle for the method described herein; and the cycle can be repeated until the desired thickness of a film is obtained.

For multi-component silicon-containing films, other precursors such as silicon-containing precursors, nitrogen-containing precursors, oxygen-containing sources, reducing agents, and/or other reagents can be alternately introduced into the reactor chamber.

In a further embodiment of the method described herein, the silicon-containing film is deposited using a thermal CVD process. In this embodiment, the method comprises:
a. placing one or more substrates into a reactor which is heated to one or more temperatures ranging from ambient temperature to about 700° C.;
b. introducing at least one monoorganoaminodisilane precursor comprising only one organoamino group connected to an Si—H₂ group and one Si—Si bond represented by the following Formula I below:

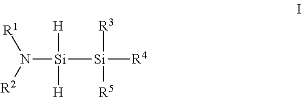

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
c. providing a nitrogen-containing source into the reactor to at least partially react with the at least one monoorganoaminodisilane precursor and deposit a silicon-containing film onto the one or more substrates. In certain embodiments of the CVD method, the reactor is maintained at a pressure ranging from 10 mTorr to 760 Torr during the introducing step.

In a further embodiment of the method described herein, an silicon-containing film which may be amorphous or crystalline, and in one embodiment is a silicon carbonitride film, is deposited using the Formula I precursor described herein. In this embodiment, the method comprises:
a. placing one or more substrates into a reactor which is heated to a one or more temperatures ranging from ambient temperature to about 700° C.;
b. introducing at least one monoorganoaminodisilane precursor represented by the following Formula I below:

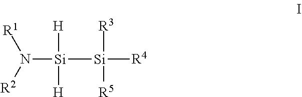

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
c. purging the reactor with a purge gas;
d. providing a plasma source into the reactor to at least partially react with the at least one monoorganoaminodisilane precursor and deposit a silicon-containing film onto the one or more substrates; and
e. purging the reactor with a purge gas.

In the method described above, steps b to e define one cycle and the cycle(s) can be repeated until the desired thickness of a film is obtained. The thickness of the film ranges from about 0.1 Å to about 1000 Å, or from about 0.1 Å to about 100 Å, or from about 0.1 Å to about 10 Å. The plasma source is selected from the group consisting of: a plasma comprising hydrogen and argon, a plasma comprising hydrogen and helium, an argon plasma, a helium plasma, other noble gas(es) (e.g., neon (Ne), krypton (Kr), and xenon (Xe)) plasma, and combinations thereof. In one particular embodiment of the method, the silicon-containing film comprises silicon carbonitride.

In certain embodiments, the monoorganoaminodisilane precursors having Formula I described herein can also be used as a dopant for metal containing films, such as but not limited to, metal oxide films or metal nitride films. In these embodiments, the metal containing film is deposited using an ALD or CVD process such as those processes described herein using metal alkoxide, metal amide, or volatile organometallic precursors. Examples of suitable metal alkoxide precursors that may be used with the method disclosed herein include, but are not limited to, group 3 to 6 metal alkoxide, group 3 to 6 metal complexes having both alkoxy and alkyl substituted cyclopentadienyl ligands, group 3 to 6 metal complexes having both alkoxy and alkyl substituted pyrrolyl ligands, group 3 to 6 metal complexes having both alkoxy and diketonate ligands; group 3 to 6 metal complexes having both alkoxy and ketoester ligands; Examples of suitable metal amide precursors that may be used with the method disclosed herein include, but are not limited to, tetrakis(dimethylamino)zirconium (TDMAZ), tetrakis(diethylamino)zirconium (TDEAZ), tetrakis(ethylmethylamino)zirconium (TEMAZ), tetrakis(dimethylamino)hafnium (TDMAH), tetrakis(diethylamino)hafnium (TDEAH), and tetrakis(ethylmethylamino)hafnium (TEMAH), tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten, and combinations thereof. Examples of suitable organometallic precursors that may be used with the method disclosed herein include, but are not limited to, group 3 metal cyclopentadienyls or alkyl cyclopentadienyls. Exemplary Group 3 to 6 metal herein include, but not limited to, Y, La, Ce, Pr, Nd, Sm, Eu, Gd, Tb, Dy, Er, Yb, Lu, Ti, Hf, Zr, V, Nb, Ta, Cr, Mo, and W.

In certain embodiments, the resultant silicon-containing films or coatings can be exposed to a post-deposition treatment such as, but not limited to, a plasma treatment, chemical treatment, ultraviolet light exposure, electron beam exposure, and/or other treatments to affect one or more properties of the film.

In certain embodiments, the silicon-containing films described herein have a dielectric constant of 6 or less. In these or other embodiments, the films can a dielectric constant of about 5 or below, or about 4 or below, or about 3.5 or below. However, it is envisioned that films having other dielectric constants (e.g., higher or lower) can be formed depending upon the desired end-use of the film. An example of the silicon containing or silicon-containing film that is formed using the monoorganoaminodisilane precursors and processes described herein has the formulation SiₓO_{y}C_{z}NᵥH_{w} wherein Si ranges from about 10% to about 40%; 0 ranges from about 0% to about 65%; C ranges from about 0% to about 75% or from about 0% to about 50%; N ranges from about 0% to about 75% or from about 0% to 50%; and H ranges from about 0% to about 50% atomic percent weight % wherein x+y+z+v+w=100 atomic weight percent, as determined for example, by XPS or other means. Another example of the silicon containing film that is formed using the monoorganoaminodisilane precursors and processes described herein is silicon carbonitride wherein the carbon content is from 1 at % to 80 at % measured by XPS. In yet, another example of the silicon containing film that is formed using the monoorganoaminodisilane precursors and processes described herein is amorphous silicon wherein both sum of nitrogen and carbon contents is <10 at %, preferably <5 at %, most preferably <1 at % measured by XPS.

As mentioned previously, the method described herein may be used to deposit a silicon-containing film on at least a portion of a substrate. Examples of suitable substrates include but are not limited to, silicon, germanium doped silicon, germanium, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, a flexible substrate, organic polymers, porous organic and inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

The deposited films have applications, which include, but are not limited to, computer chips, optical devices, magnetic information storages, coatings on a supporting material or substrate, microelectromechanical systems (MEMS), nanoelectromechanical systems, thin film transistor (TFT), light emitting diodes (LED), organic light emitting diodes (OLED), IGZO, and liquid crystal displays (LCD).

The following examples illustrate the method for preparing monoorganoaminodisilane precursors as well as depositing silicon-containing films described herein and are not intended to limit it in any way.

### EXAMPLES

In the following examples, unless stated otherwise, properties were obtained from sample films that were deposited onto medium resistivity (8-12 Ωcm) single crystal silicon wafer substrates.

### Example 1: Synthesis of 1-di-iso-propylamino-2,2,2-trimethyldisilane (Prophetic)

In a 3-necked round bottom flask equipped with a mechanic stirrer, a condenser, and an addition funnel, a solution of 1 equivalent 1,1,1-trichloro-2,2,2-trimethyldisilane in hexane is cooled to −10° C. with a cold bath. With stirring, 2 equivalent of di-iso-propylamine iss added dropwise through the addition funnel. After the addition is completed, the reaction mixture iss allowed to warm up to room temperature. The reaction mixture is stirred at room temperature for 2 hours, followed by filtration. A distillation removes solvent hexane from the filtrate. The product di-iso-propylaminodichloro-2-2-2-trimethyldisilane iss obtained by vacuum distillation. Di-iso-propylamino-2-2-2-trimethyldisilane can be made via reaction of di-iso-propylaminodichloro-2-2-2-trimethyldisilane with LiH, followed by vacuum distillation.

Alternatively di-iso-propylaminodichloro-2-2-2-trimethyldisilane can also be made via dehydro-coupling of di-iso-propylaminosilane with trimethylsilane in presence of a catalyst.

### Example 2: Synthesis of 1-di-iso-propylamino-2,2-diethyldisilane (Prophetic)

To 0.20 g (1.52 mmol) di-iso-propylaminosilane in 3 mL of anhydrous THF is added 0.20 g (2.27 mmol) diethylsilane followed by addition of 1.5% molar loading of Petasis reagent in THF. After approximately 20 minutes the yellow solution becomes dark blue. The reaction is heated at 50° C. for several hours and an aliquot is sampled, filtered, and ran on GC-MS and shows the formation of the desired 1-di-iso-propylamino-2,2-diethyldisilane with a parent peak of 217 amu.

### Example 3: PEALD Silicon Oxide Using 1-di-iso-propylamino-2,2,2-trimethyldisilane in Laminar Flow Reactor with 27.1 MHz Plasma (Prophetic)

Depositions are performed with 1-di-iso-propylamino-2,2,2-trimethyldisilane as the silicon precursor and 02 plasma under conditions as described above in Table 1. The silicon precursor is delivered to chamber with carrier gas Ar flow of 200 sccm. Steps b to e are repeated many times to get a desired thickness of silicon oxide for metrology. The growth rate per cycle (GPC) is expected to be 1.5 Å/cycle.

TABLE 1
Process for PEALD Silicon Oxide Deposition in the
Commercial Lateral Flow PEALD Reactor with 1-di-iso-
propylamino-2,2,2-trimethyldisilane as Silicon Precursor

| Step | | |
|---|---|---|
| a | Introduce Si wafer | Deposition temperature = |
| | to the reactor | 100° C. or 300° C. |
| b | Introduce silicon | Carrier gas precursor |
| | precursor to the | delivery = variable |
| | reactor | seconds with 200 sccm Ar; |
| | | Process gas Argon |
| | | flow = 300 sccm |
| | | Reactor pressure = 2 or 3 Torr |
| c | Purge silicon | Argon flow = 300 sccm |
| | precursor with inert | Reactor pressure = 2 or 3 Torr |
| | gas (argon) | |
| d | Oxidation using | Argon flow = 300 sccm |
| | plasma | Oxygen flow = 100 sccm |
| | | Plasma power = 200 W |
| | | Plasma time = variable seconds |
| | | Reactor pressure = 2 or 3 Torr |
| e | Purge O₂ plasma | Plasma off |
| | | Argon flow = 300 sccm |
| | | Argon flow time = 5 seconds |
| | | Reactor pressure = 2 or 3 Torr |

Although the disclosure has been described with reference to certain preferred embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments, but that the invention will include all embodiments falling within the scope of the appended claims.

1. A composition comprising an monoorganoaminodisilane represented by the structure of Formula I: 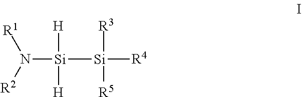
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen, wherein the composition is substantially free of halide ions.

2. The composition of claim 1 wherein the R¹ and R² are linked together to form a ring.

3. The composition of claim 1 wherein R³⁻⁵ are each independently selected from hydrogen, methyl or ethyl.

4. The composition of claim 3 wherein the monoorganoaminodisilane is selected from the group consisting of 1-dimethylamino-2,2,2-trimethyldisilane, 1-diethylamino-2,2,2-trimethyldisilane, 1-ethylmethylamino-2,2,2-trimethyldisilane, 1-di-n-propylamino-2,2,2-trimethyldisilane, 1-di-iso-propylamino-2,2,2-trimethyldisilane, 1-di-sec-butylamino-2,2,2-trimethyldisilane, 1-di-iso-butylamino-2,2,2-trimethyldisilane, 1-dimethylamino-2,2-dimethyldisilane, 1-diethylamino-2,2-dimethyldisilane, 1-ethylmethylamino-2,2-dimethyldisilane, 1-di-n-propylamino-2,2-dimethyldisilane, 1-di-iso-propylamino-2,2-dimethyldisilane, 1-di-n-butylamino-2,2-dimethyldisilane, 1-di-iso-butylamino-2,2-dimethyldisilane, 1-di-iso-butylamino-2,2-dimethyldisilane, 1-di-sec-butylamino-2,2-dimethyldisilane, 1-dimethylamino-2-methyldisilane, 1-diethylamino-2-methyldisilane, 1-di-n-propylamino-2-methyldisilane, 1-di-iso-propylamino-2-methyldisilane, 1-di-n-butylamino-2-methyldisilane, 1-di-iso-butylamino-2-methyldisilane, 1-di-sec-butylamino-2-methyldisilane, 1-dimethylamino-2,2,2-triethyldisilane, 1-diethylamino-2,2,2-triethyldisilane, 1-di-iso-propylamino-2,2,2-triethyldisilane, 1-di-sec-butylamino-2,2,2-triethyldisilane, 1-dimethylamino-2,2-diethyldisilane, 1-diethylamino-2,2-diethyldisilane, 1-pyrrolidino-2,2,2-trimethyldisilane, 1-piperidino-2,2,2-trimethyldisilane, 1-2,5-dimethylpyrrolidino-2,2,2-trimethyldisilane, 1-2,6-dimethylpiperidino-2,2,2-trimethyldisilane, 1-pyrrolidino-2,2-dimethyldisilane, 1-piperidino-2,2-dimethyldisilane, 1-2,5-dimethylpyrrolidino-2,2-dimethyldisilane, 1-2,6-dimethylpiperidino-2,2-dimethyldisilane, 1-pyrrolidino-2-methyldisilane, 1-piperidino-2-methyldisilane, 1-2,5-dimethylpyrrolidino-2-methyldisilane, 1-2,6-dimethylpiperidino-2-methyldisilane, 1-pyrrolidino-2,2-diethyldisilane, 1-piperidino-2,2-diethyldisilane, 1-2,5-dimethylpyrrolidino-2,2-diethyldisilane, 1-2,6-dimethylpiperidino-2,2-dimethyldisilane, 1-pyrrolidino-2-ethyldisilane, 1-piperidino-2-ethyldisilane, 1-2,5-dimethylpyrrolidino-2-ethyldisilane, and 1-2,6-dimethylpiperidino-2-ethyldisilane.

5. The composition of claim 1 wherein the halide ions are chloride ions.

6. The composition of claim 1 which comprises less than 5 ppm of chloride ions.

7. The composition of claim 1 which comprises less than 3 ppm of chloride ions.

8. The composition of claim 1 which comprises less than 1 ppm of chloride ions.

9. A composition comprising:
(a) at least one monoorganoaminodisilane represented by Formula I: 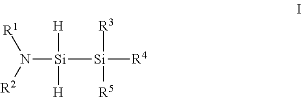
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
(b) a solvent, wherein the solvent has a boiling point, wherein the difference between the boiling point of the solvent and that of the at least one monoorganoaminodisilane is 40° C. or less, and wherein the composition is substantially free of halide ions.

10. The composition of claim 9 wherein the monoorganoaminodisilane precursor comprises at least one selected from the group consisting of 1-dimethylamino-2,2,2-trimethyldisilane, 1-diethylamino-2,2,2-trimethyldisilane, 1-ethylmethylamino-2,2,2-trimethyldisilane, 1-di-n-propylamino-2,2,2-trimethyldisilane, 1-di-iso-propylamino-2,2,2-trimethyldisilane, 1-di-sec-butylamino-2,2,2-trimethyldisilane, 1-di-iso-butylamino-2,2,2-trimethyldisilane, 1-dimethylamino-2,2-dimethyldisilane, 1-diethylamino-2,2-dimethyldisilane, 1-ethylmethylamino-2,2-dimethyldisilane, 1-di-n-propylamino-2,2-dimethyldisilane, 1-di-iso-propylamino-2,2-dimethyldisilane, 1-di-n-butylamino-2,2-dimethyldisilane, 1-di-iso-butylamino-2,2-dimethyldisilane, 1-di-iso-butylamino-2,2-dimethyldisilane, 1-di-sec-butylamino-2,2-dimethyldisilane, 1-dimethylamino-2-methyldisilane, 1-diethylamino-2-methyldisilane, 1-di-n-propylamino-2-methyldisilane, 1-di-iso-propylamino-2-methyldisilane, 1-di-n-butylamino-2-methyldisilane, 1-di-iso-butylamino-2-methyldisilane, 1-di-sec-butylamino-2-methyldisilane, 1-dimethylamino-2,2,2-triethyldisilane, 1-diethylamino-2,2,2-triethyldisilane, 1-di-iso-propylamino-2,2,2-triethyldisilane, 1-di-sec-butylamino-2,2,2-triethyldisilane, 1-dimethylamino-2,2-diethyldisilane, 1-diethylamino-2,2-diethyldisilane, 1-pyrrolidino-2,2,2-trimethyldisilane, 1-piperidino-2,2,2-trimethyldisilane, 1-2,5-dimethylpyrrolidino-2,2,2-trimethyldisilane, 1-2,6-dimethylpiperidino-2,2,2-trimethyldisilane, 1-pyrrolidino-2,2-dimethyldisilane, 1-piperidino-2,2-dimethyldisilane, 1-2,5-dimethylpyrrolidino-2,2-dimethyldisilane, 1-2,6-dimethylpiperidino-2,2-dimethyldisilane, 1-pyrrolidino-2-methyldisilane, 1-piperidino-2-methyldisilane, 1-2,5-dimethylpyrrolidino-2-methyldisilane, 1-2,6-dimethylpiperidino-2-methyldisilane, 1-pyrrolidino-2,2-diethyldisilane, 1-piperidino-2,2-diethyldisilane, 1-2,5-dimethylpyrrolidino-2,2-diethyldisilane, 1-2,6-dimethylpiperidino-2,2-dimethyldisilane, 1-pyrrolidino-2-ethyldisilane, 1-piperidino-2-ethyldisilane, 1-2,5-dimethylpyrrolidino-2-ethyldisilane, and 1-2,6-dimethylpiperidino-2-ethyldisilane.

11. The composition of claim 9 wherein the solvent comprises at least one selected from the group consisting of ether, tertiary amine, alkyl hydrocarbon, aromatic hydrocarbon, and tertiary aminoether.

12. A method for forming a silicon-containing film on at least one surface of a substrate by a deposition process selected from a chemical vapor deposition process and an atomic layer deposition process, the method comprising:
providing the at least one surface of the substrate in a reaction chamber;
introducing at least one monoorganoaminodisilane having a structure of Formula I: 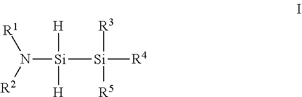
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen; and
introducing a nitrogen-containing source into the reactor wherein the at least one monoorganoaminodisilane precursor and the nitrogen-containing source react to form the film on the at least one surface, wherein the monoorganoaminodisilane is substantially free of halide ions.

13. The method of claim 12 wherein the at least one monoorganoaminodisilane is selected from the group consisting of 1-dimethylamino-2,2,2-trimethyldisilane, 1-diethylamino-2,2,2-trimethyldisilane, 1-ethylmethylamino-2,2,2-trimethyldisilane, 1-di-n-propylamino-2,2,2-trimethyldisilane, 1-di-iso-propylamino-2,2,2-trimethyldisilane, 1-di-sec-butylamino-2,2,2-trimethyldisilane, 1-di-iso-butylamino-2,2,2-trimethyldisilane, 1-dimethylamino-2,2-dimethyldisilane, 1-diethylamino-2,2-dimethyldisilane, 1-ethylmethylamino-2,2-dimethyldisilane, 1-di-n-propylamino-2,2-dimethyldisilane, 1-di-iso-propylamino-2,2-dimethyldisilane, 1-di-n-butylamino-2,2-dimethyldisilane, 1-di-iso-butylamino-2,2-dimethyldisilane, 1-di-iso-butylamino-2,2-dimethyldisilane, 1-di-sec-butylamino-2,2-dimethyldisilane, 1-dimethylamino-2-methyldisilane, 1-diethylamino-2-methyldisilane, 1-di-n-propylamino-2-methyldisilane, 1-di-iso-propylamino-2-methyldisilane, 1-di-n-butylamino-2-methyldisilane, 1-di-iso-butylamino-2-methyldisilane, 1-di-sec-butylamino-2-methyldisilane, 1-dimethylamino-2,2,2-triethyldisilane, 1-diethylamino-2,2,2-triethyldisilane, 1-di-iso-propylamino-2,2,2-triethyldisilane, 1-di-sec-butylamino-2,2,2-triethyldisilane, 1-dimethylamino-2,2-diethyldisilane, 1-diethylamino-2,2-diethyldisilane, 1-pyrrolidino-2,2,2-trimethyldisilane, 1-piperidino-2,2,2-trimethyldisilane, 1-2,5-dimethylpyrrolidino-2,2,2-trimethyldisilane, 1-2,6-dimethylpiperidino-2,2,2-trimethyldisilane, 1-pyrrolidino-2,2-dimethyldisilane, 1-piperidino-2,2-dimethyldisilane, 1-2,5-dimethylpyrrolidino-2,2-dimethyldisilane, 1-2,6-dimethylpiperidino-2,2-dimethyldisilane, 1-pyrrolidino-2-methyldisilane, 1-piperidino-2-methyldisilane, 1-2,5-dimethylpyrrolidino-2-methyldisilane, 1-2,6-dimethylpiperidino-2-methyldisilane, 1-pyrrolidino-2,2-diethyldisilane, 1-piperidino-2,2-diethyldisilane, 1-2,5-dimethylpyrrolidino-2,2-diethyldisilane, 1-2,6-dimethylpiperidino-2,2-dimethyldisilane, 1-pyrrolidino-2-ethyldisilane, 1-piperidino-2-ethyldisilane, 1-2,5-dimethylpyrrolidino-2-ethyldisilane, and 1-2,6-dimethylpiperidino-2-ethyldisilane.

14. The method of claim 12 wherein the nitrogen-containing source is selected from the group consisting of ammonia, hydrazine, monoalkylhydrazine, dialkylhydrazine, nitrogen, nitrogen/hydrogen, ammonia plasma, nitrogen plasma, nitrogen/hydrogen plasma, and mixtures thereof. (would we ever make plasma from hydrazine or its derivatives?)

15. The method of claim 12 wherein the silicon-containing film is selected from the group consisting of silicon nitride and silicon carbonitride.

16. A method of forming a silicon-containing film wherein the film is selected from an amorphous and a crystalline film from a deposition process selected from by plasma enhanced atomic layer deposition and plasma enhanced cyclic chemical vapor deposition, the method comprising:
placing one or more substrates into a reactor which is heated to a one or more temperatures ranging from ambient temperature to about 700° C.;
introducing at least one monoorganoaminodisilane precursor comprising a compound having Formula I below: 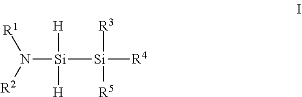
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, optionally wherein R¹ and R² are linked together to form a ring selected from a substituted or unsubstituted aromatic ring or a substituted or unsubstituted aliphatic ring; and R³⁻⁵ are each independently selected from hydrogen, a linear or branched C₁ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group, with the proviso that R³⁻⁵ cannot be all hydrogen and wherein the monoorganoaminodisilane is substantially free of halide ions;
purging the reactor with a purge gas;
providing a plasma source into the reactor to at least partially react with the at least one monoorganoaminodisilane precursor and deposit a silicon-containing film onto the one or more substrates; and
purging the reactor with a purge gas.

17. The method of claim 16 wherein the plasma source is selected from the group consisting of a plasma comprising hydrogen and argon, a plasma comprising hydrogen and helium plasma, an argon plasma, a helium plasma, and mixtures thereof.

18. The method of claim 16 wherein the at least one monoorganoaminodisilane is selected from the group consisting of 1-dimethylamino-2,2,2-trimethyldisilane, 1-diethylamino-2,2,2-trimethyldisilane, 1-ethylmethylamino-2,2,2-trimethyldisilane, 1-di-n-propylamino-2,2,2-trimethyldisilane, 1-di-iso-propylamino-2,2,2-trimethyldisilane, 1-di-sec-butylamino-2,2,2-trimethyldisilane, 1-di-iso-butylamino-2,2,2-trimethyldisilane, 1-dimethylamino-2,2-dimethyldisilane, 1-diethylamino-2,2-dimethyldisilane, 1-ethylmethylamino-2,2-dimethyldisilane, 1-di-n-propylamino-2,2-dimethyldisilane, 1-di-iso-propylamino-2,2-dimethyldisilane, 1-di-n-butylamino-2,2-dimethyldisilane, 1-di-iso-butylamino-2,2-dimethyldisilane, 1-di-iso-butylamino-2,2-dimethyldisilane, 1-di-sec-butylamino-2,2-dimethyldisilane, 1-dimethylamino-2-methyldisilane, 1-diethylamino-2-methyldisilane, 1-di-n-propylamino-2-methyldisilane, 1-di-iso-propylamino-2-methyldisilane, 1-di-n-butylamino-2-methyldisilane, 1-di-iso-butylamino-2-methyldisilane, 1-di-sec-butylamino-2-methyldisilane, 1-dimethylamino-2,2,2-triethyldisilane, 1-diethylamino-2,2,2-triethyldisilane, 1-di-iso-propylamino-2,2,2-triethyldisilane, 1-di-sec-butylamino-2,2,2-triethyldisilane, 1-dimethylamino-2,2-diethyldisilane, 1-diethylamino-2,2-diethyldisilane, 1-pyrrolidino-2,2,2-trimethyldisilane, 1-piperidino-2,2,2-trimethyldisilane, 1-2,5-dimethylpyrrolidino-2,2,2-trimethyldisilane, 1-2,6-dimethylpiperidino-2,2,2-trimethyldisilane, 1-pyrrolidino-2,2-dimethyldisilane, 1-piperidino-2,2-dimethyldisilane, 1-2,5-dimethylpyrrolidino-2,2-dimethyldisilane, 1-2,6-dimethylpiperidino-2,2-dimethyldisilane, 1-pyrrolidino-2-methyldisilane, 1-piperidino-2-methyldisilane, 1-2,5-dimethylpyrrolidino-2-methyldisilane, 1-2,6-dimethylpiperidino-2-methyldisilane, 1-pyrrolidino-2,2-diethyldisilane, 1-piperidino-2,2-diethyldisilane, 1-2,5-dimethylpyrrolidino-2,2-diethyldisilane, 1-2,6-dimethylpiperidino-2,2-dimethyldisilane, 1-pyrrolidino-2-ethyldisilane, 1-piperidino-2-ethyldisilane, 1-2,5-dimethylpyrrolidino-2-ethyldisilane, and 1-2,6-dimethylpiperidino-2-ethyldisilane.
